(19) United States
(12) Patent Application Publication
(10) Pub. No.: US 2015/0380169 A1
(43) Pub. Date: Dec. 31, 2015

(54) Surface-Passivated Mesoporous Structure Solar Cell

(71) Applicant: Sharp Laboratories of America, Inc., Camas, WA (US)

(72) Inventors: Changqing Zhan, Vancouver, WA (US); Alexey Koposov, Vancouver, WA (US); Wei Pan, Vancouver, WA (US)

(21) Appl. No.: 14/320,488

(22) Filed: Jun. 30, 2014

(51) Int. Cl. H01G 9/20; H01L 51/00

(52) U.S. Cl. CPC H01G 9/2031; H01G 9/2027; H01G 9/2059; H01L 51/0084

(57) ABSTRACT

A method is presented for forming a surface-passivated mesoporous-structured solar cell. The method provides a transparent substrate, and forms an overlying transparent conductive electrode. A non-mesoporous layer of a first metal oxide is formed overlying the transparent conductive electrode. A mesoporous structure is formed overlying the non-mesoporous layer of first metal oxide. The mesoporous structure includes a mesoporous layer of a second metal oxide over the first metal oxide layer, and coating the mesoporous layer of second metal oxide is a passivating semiconductor layer having a bandgap wider than the second metal oxide. A semiconductor absorber layer is formed overlying the mesoporous structure, which is made up of both organic and inorganic components. A hole-transport medium (HTM) layer is formed overlying the semiconductor absorber layer, which may be an organic material. A metal electrode overlies the HTM layer. Also provided is a surface-passivated mesoporous-structured solar cell and ambipolar material.

### BACKGROUND OF THE INVENTION

1. Field of the Invention

This invention generally relates to solar cells and, more particularly, to a surface-passivated mesoporous-structure solar cell.

2. Description of the Related Art

As evolved from dye-sensitized solar cells (DSSCs or DSCs), perovskite-sensitized solar-cells have recently attracted a great deal attention with a record high efficiency breakthrough (>17%) based upon low cost organometal trihalide perovskite absorbers. It has been suggested that with optimization of the cell structure, light absorber, and hole conducting material, this technology could advance to an efficiency that surpasses that of copper indium gallium (di)selenide (CIGS) (20%) and approaches crystalline silicon (25%). Conventional perovskite based solar cells use two common types of architecture: flat and mesoscopic. With the flat architecture, one absorber layer is deposited directly on a flat titanium oxide (TiO₂) surface forming a thin film, in a fashion similar to thin film solar cells. The second approach adopts a configuration similar to solid dye-sensitized solar cells.

FIG. 1 is a partial cross-sectional view of a perovskite solar cell structure (prior art). As depicted in the figure, a mesostructured perovskite-based solar cell structure is composed of a FTO glass substrate 102 as anode, a thin layer of compact TiO₂ layer 104 deposited by spray pyrolysis, followed by about 300-500 nanometers (nm) of mesoporous spin-coated or printed TiO₂ 106, which serves both as the electron transporter and the “scaffold” on which the perovskite absorber 108 is coated using a solution based process. A hole transport material (HTM) 110 (e.g., spiro-OMeTAD) is coated over the perovskite absorber 108, and on top of the solar cell is a gold electrode 112 formed by evaporation.

The mesoporous TiO₂ electrode 106 has long been the most commonly used electron transporter material since the advent of liquid DSC. This porous TiO₂ structure provides sufficient internal surface area to which dye molecules can attach, and, therefore maximize light harvesting efficiency. The electron transfer from selected dyes to the porous TiO₂ electrode is not only a favored process but also is much faster than other recombination processes, making porous TiO₂ an indispensable photo anode for DSC.

FIG. 2 is a diagram depicting electron and hole transport processes in a perovskite sensitized TiO₂ solar cell (prior art). However, when the hybrid organic/inorganic trihalide perovskite is deposited onto and within the porous TiO₂ scaffold, the interface character changes from dye-TiO₂ to perovskite-TiO₂. It has been found that the deep electron traps in the TiO₂ are responsible for a loss in electron collection efficiency and open-circuit voltage in the perovskite cells, as well as facilitating the degradation of the absorber layer.

After incident light is absorbed in the perovskite, electrons would be transferred to the TiO₂, and holes would be transferred by the spiro-OMeTAD (HTM) to counter electrode. Alternatively, it has been suggested that electrons do not go into mesoporous TiO₂, but travel to compact layer through perovskite. Regardless of the exact transfer mechanism however, the interfacial traps on the surface of mesoporous TiO₂ increase the recombination probability at the interfaces. The open circuit voltage diminishes, as does the overall conversion efficiency of the cell. In addition, such trap sites could participate in the photodegradation of the perovskite layer. Therefore, the eliminating or passivating of these interfacial traps is crucial for such cells to reach higher performance levels. Note: “hv” stands for one photon of light.

In the study of perovskite's charge transport properties, it has been reported that perovskite can exhibit ambipolar charge transport—i.e., the transport of both electrons and holes. However, this ambipolar characteristic could only be demonstrated in a cell without using a TiO₂ mesoporous layer, where an insulator aluminum oxide (Al₂O₃) mesoporous layer was used. As a result, the only path for electron transfer was through the perovskite. For a solar cell with a TiO₂ mesoporous layer as depicted in FIG. 1, the photo excited electrons could theoretically be transferred through both the TiO₂ network and the perovskite. However, since the electron trap sites and the TiO₂ exhibit a faster electron transfer speed than the perovskite, the perovskite's electron transport cannot be established.

It would be advantageous if a mesoporous structure solar cell could be fabricated to take advantage of electron transport through mesoporous layer.

### SUMMARY OF THE INVENTION

It is clear that there are two major paths to further improve the power conversion efficiency of perovskite solar cells: one is to establish a new cell structure, as does the Oxford photovoltaic (PV) group, in which the mesoporous TiO₂ is replaced by a mesoporous Al₂O₃ layer. The other approach, disclosed herein, is to retain the mesoporous metal oxide (e.g., titanium oxide: TiO₂) structure, but incorporate surface passivation using special coatings. The later approach is a simple and straightforward approach with the benefit maintaining the low cost fabrication advantage associated with this general type of dye-sensitized solar cell. Advantageously, this approach uses existing dye-sensitized solar cell fabrication infrastructure.

The surface-passivated mesoporous structure solar cell disclosed herein improves power conversion efficiency through the creation of a trap-free interface between an absorber layer and a mesoporous metal oxide layer by passivating the electron traps on the surface of the mesoporous metal oxide using an electron trap free passivating semiconductor material, such as aluminum oxide (Al₂O₃), without altering the low cost solution processing nature of perovskite absorber deposition. While inheriting all the advantages of the solution-based perovskite sensitized solid-state solar cell structure, including its fabrication process flow, simple structure, high power conversion efficiency, low cost, and easy up-scaling, the addition of the extra thin layer passivating semiconductor layer enables this new structure solar cell to utilize the recently discovered unique property of perovskite, which is that of an ambipolar charge transporter. The passivating semiconductor also passivates the mesoporous metal oxide surface and, therefore, significant improves electrons collection efficiency while diminishing charge recombination.

Accordingly, a method is presented for forming a surface-passivated mesoporous-structured solar cell. The method provides a transparent substrate, and forms an overlying transparent conductive electrode. A non-mesoporous layer of a first metal oxide is formed overlying the transparent conductive electrode. A mesoporous structure is formed overlying the non-mesoporous layer of first metal oxide. The mesoporous structure includes a mesoporous layer of a second metal oxide over the first metal oxide layer, and coating the mesoporous layer of second metal oxide is a passivating semiconductor layer having a bandgap wider than the second metal oxide. A semiconductor absorber layer is formed overlying the mesoporous structure, which is prepared from organic and inorganic precursors. A hole-transport medium (HTM) layer is formed overlying the semiconductor absorber layer, which may be an organic material. A metal electrode overlies the HTM layer.

The first and second metal oxides are independently selected (are the same or a different material), and may be titanium oxide (TiO₂), tin oxide (SnO₂), zinc oxide (ZnO), niobium oxide (Nb₂O₅), tantalum oxide (Ta₂O₅), barium titanate (BaTiO₃), strontium titanate (SrTiO₃), zinc titanate (ZnTiO₃), or copper titanate (CuTiO₃). The passivating semiconductor may be aluminum oxide (Al₂O₃), silicon oxide (SiO₂), or zirconium oxide (ZrO₂). The semiconductor absorber has the general formula of ABX_{Z}Y_{3-Z};

where “A” is an organic monocation;

where B is a transition metal dication;

where X and Y are inorganic monoanions; and,

where z is in a range of 0 to 1.5.

Additional details of the above-described method, a passivated mesoscopic metal oxide, and a surface-passivated mesoporous-structured solar cell are presented below.

### BRIEF DESCRIPTION OF THE DRAWINGS

FIG. 1 is a partial cross-sectional view of a perovskite solar cell structure (prior art).

FIG. 2 is a diagram depicting electron and hole transport processes in a perovskite sensitized TiO₂ solar cell (prior art).

FIG. 3 is a partial cross-sectional view of a surface-passivated mesoporous-structured solar cell.

FIG. 4 is a diagram depicting charge transport in the solar cell device of FIG. 3.

FIG. 5 is a flowchart illustrating the fabrication process flow of a perovskite solar cell with a TiO/Al₂O₃ bi-layered mesoporous scaffold structure.

FIG. 6 is a flowchart illustrating a method for forming a passsivated mesoscopic metal oxide.

FIG. 7 is a flowchart illustrating a method for forming a surface-passivated mesoporous-structured solar cell.

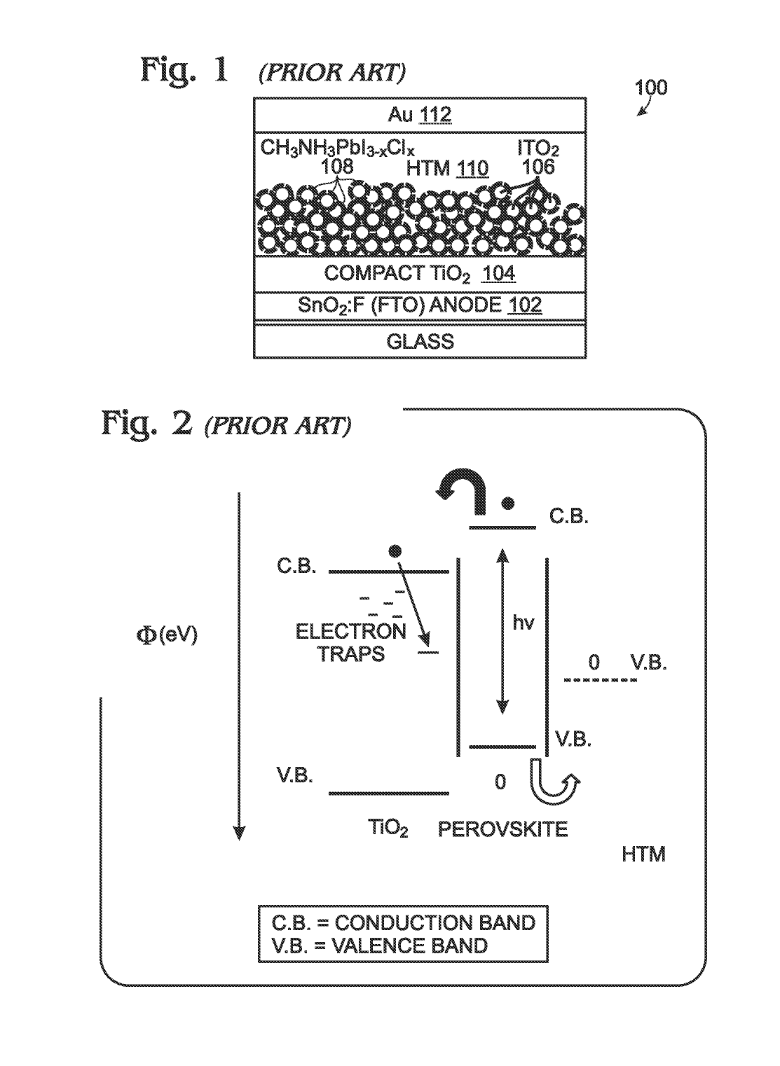

### DETAILED DESCRIPTION

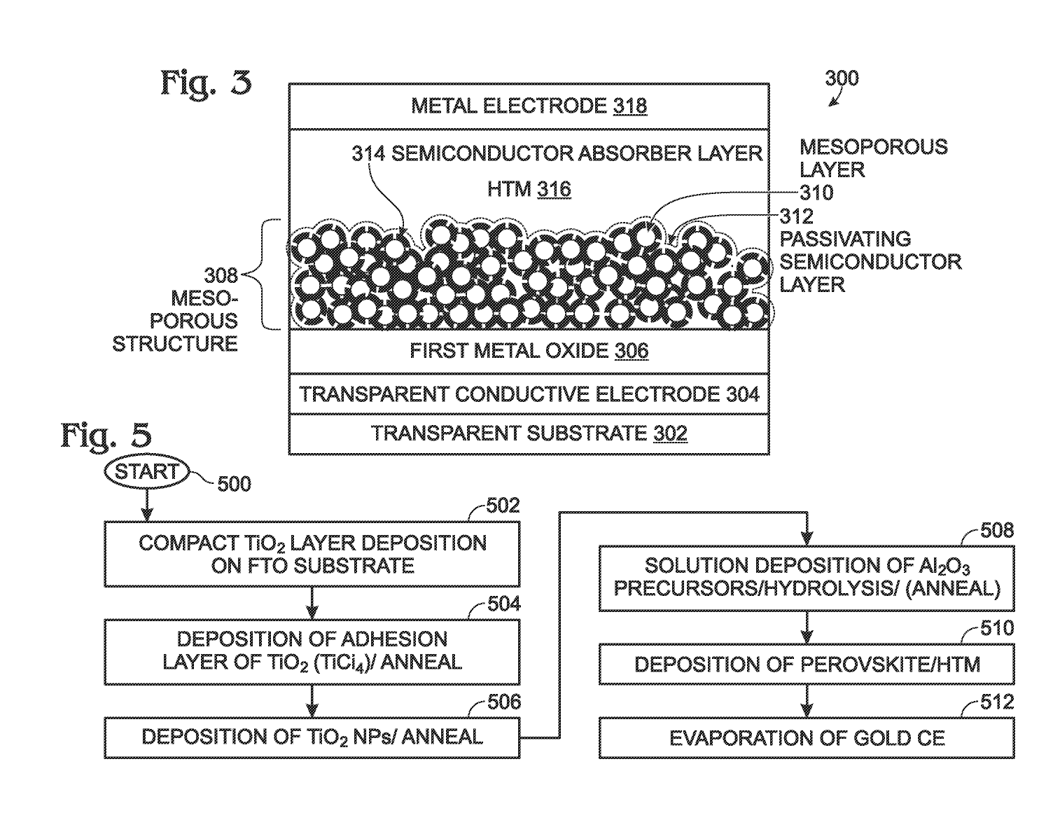

FIG. 3 is a partial cross-sectional view of a surface-passivated mesoporous-structured solar cell. The solar cell 300 comprises a transparent substrate 302. Silica (glass), quartz, or a plastic may be used as the transparent substrate 302. A transparent conductive electrode 304 overlies the transparent substrate 302. Fluorine-doped tin oxide (SnO₂:F), or conductive oxides, such as indium tin oxide (ITO) or indium gallium zinc oxide (IGZO), can be used as the transparent conductive electrode 304. A non-mesoporous layer of a first metal oxide 306 overlies the transparent conductive electrode 304. A mesoporous structure 308 overlies the non-mesoporous layer of first metal oxide 306. The mesoporous structure 308 comprises a mesoporous layer of a second metal oxide 310, and a passivating semiconductor layer 312 coating the mesoporous layer of second metal oxide 310. The passivating semiconductor layer material has a bandgap wider than the second metal oxide material. Typically, the passivating semiconductor layer 312 has a bandgap greater than 3 electron volts (eV). A mesoporous material is a material containing pores with diameters between 2 and 50 nanometers (nm).

As is well known in the art, a bandgap is the range between the valence band and the conduction band, in which electron states cannot exist. More explicitly, the bandgap can be defined as the difference in energy, as expressed in electron volts, between the top of the valence band and the bottom of the conduction band of insulator and semiconductor materials. This is equivalent to the energy required to free an outer shell electron from its orbit about the nucleus to become a mobile charge carrier, able to move freely within a solid material. Substances with large band gaps are generally insulators, those with smaller band gaps are semiconductors, while conductors either have very small band gaps or none, because the valence and conduction bands overlap.

A semiconductor absorber layer 314 overlies the mesoporous structure 308, and comprises organic and inorganic components. A hole-transport medium (HTM) layer 316 overlies the semiconductor absorber layer 318. In one aspect, the HTM layer 316 is an organic HTM material, such as spiro-OMeTAD. A metal electrode 316 overlies the HTM layer 316. However, the solar cell is not limited to any particular HTM material.

The first metal oxide 306 and the second metal oxide 310 are independently selected, meaning that they may be the same or a different material, such as titanium oxide (TiO₂), tin oxide (SnO₂), zinc oxide (ZnO), niobium oxide (Nb₂O₅), tantalum oxide (Ta₂O₅), barium titanate (BaTiO₃), strontium titanate (SrTiO₃), zinc titanate (ZnTiO₃), or copper titanate (CuTiO₃). The passivating semiconductor layer 312 may be a material such as aluminum oxide (Al₂O₃), silicon oxide (SiO₂), or zirconium oxide (ZrO₂), to name a few examples.

In one aspect, the mesoporous structure 308 comprises a mesoporous layer of TiO₂ nanoparticles 310, and a passivating semiconductor layer of Al₂O₃ 312 coating the TiO₂ nanoparticles. The Al₂O₃ coating 312 may have a thickness in the range of 1 to 10 nm. Alternatively, the Al₂O₃ coating 312 has a thickness of a mono-layer.

The semiconductor absorber layer 314 has a general formula of ABX_{Z}Y_{3-Z};

where “A” is an organic monocation;

where B is a transition metal dication;

where X and Y are inorganic monoanions; and,

where z is in a range of 0 to 1.5.

The organic monocation “A” is typically a substituted ammonium cation with the general formula of R¹R²R³R⁴N;

where R is hydrogen, or a compound derived from linear alkanes, branched alkanes, cycloalkanes, (poly)cycloalkanes, cis- and trans-linear alkenes, cis- and trans-branched alkenes, linear alkynes, branched alkynes, (poly)alkynes, aromatic hydrocarbons, (poly)aromatic hydrocarbons, heteroarenes, (poly)heteroarenes, thiophenes, (poly)thiophenes, (poly)anilines, or combination of above-mentioned elements.

The dication B may be Pb²⁺, Sn²⁺, Cu²⁺, Ge²⁺, Zn²⁺, Ni²⁺, Fe²⁺, Mn²⁺, Eu²⁺, or Co²⁺. The monoanions X and Y are independently selected, and may be halogenides of F—, Cl—, Br—, and I—, cyanides, or thiocyanides. For example, the semiconductor absorber layer may be a perovskite material such as CH₃NH₃Pbl_{3-Z}Cl_{X}.

Alternatively but not shown, the device structure may be reversed, so that the metal electrode is the anode and the transparent conductive electrode is the cathode.

The passivation approach used to fabricate the solar cell depicted in FIG. 3 uses the advantages of a mesoporous metal oxide (e.g., TiO₂) structure, which is a mature standard dye-sensitized solar cell (DSC) process, and a quick simple dip coating process to form a layer of passivating semiconductor (e.g., Al₂O₃). Thus, the device combines the advantages of structure and passivation. In other words, a solution-based passivating semiconductor coating step is simply added to the already existing perovskite solar cell process flow after the formation of the mesoporous metal oxide. Alternatively, the deposition may be performed using vacuum-based methods, such as atomic layer deposition (ALD) or chemical vapor deposition (CVD).

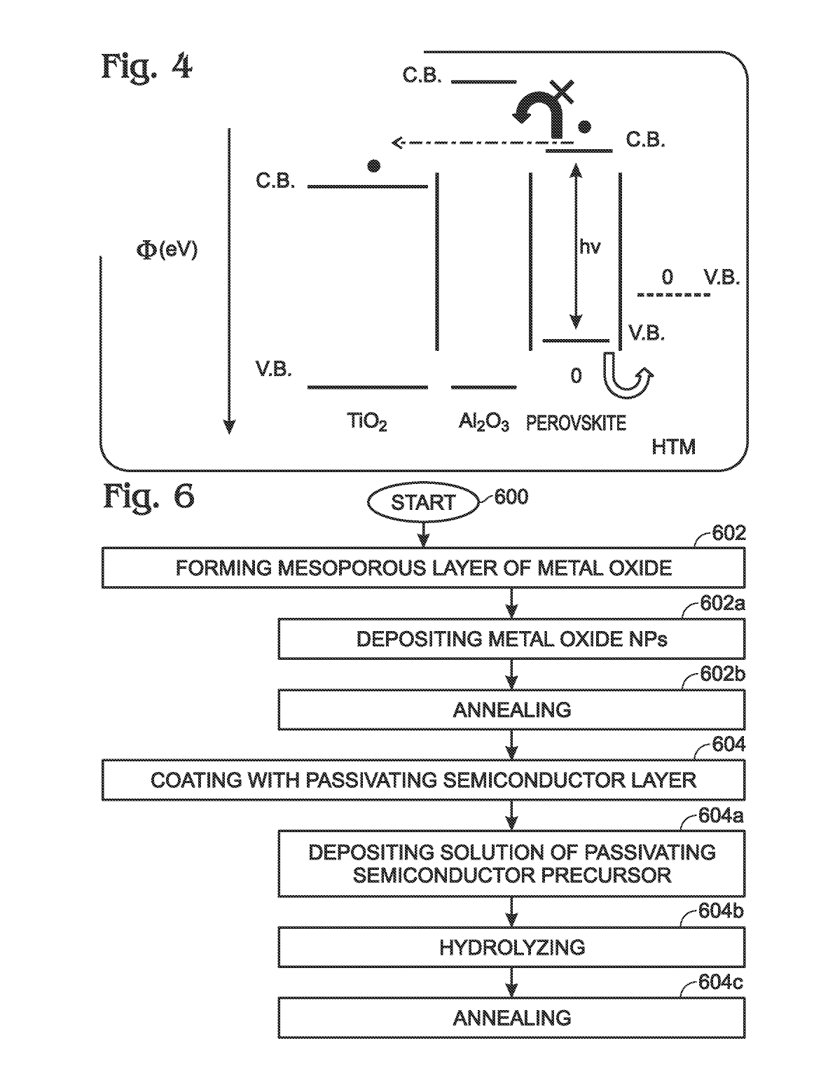

FIG. 4 is a diagram depicting charge transport in the solar cell device of FIG. 3. The following discussion uses titanium oxide and aluminum oxide as examples of a mesoporous metal oxide and a passivating semiconductor layer, respectively. However, it should be understood that the analysis provided below applied to a broader range of materials. Since the Al₂O₃ layer has a wider bandgap than the TiO₂, and if the Al₂O₃ is thick enough, photo excited electrons are only transferred through the perovskite. However, if the Al₂O₃ is thin enough, some electrons tunnel through the TiO₂, so that the TiO₂ transports those electrons to the anode. By optimizing the Al₂O₃ thickness, a significant improvement in open circuit voltage and, thus power conversion efficiency, results.

FIG. 5 is a flowchart illustrating the fabrication process flow of a perovskite solar cell with a TiO₂/Al₂O₃ bi-layered mesoporous scaffold structure. In Step 502 a compact (non-mesoporous) layer of metal oxide is deposited on a transparent conduct substrate, such as FTO. Titanium oxide and aluminum oxide are used as examples of a mesoporous metal oxide and a passivating semiconductor layer, respectively. However, it should be understood that the flowchart applies to a broader range of materials. For example, the blocking titanium oxide may be deposited by spray pyrolysis or solution-based methods, such as so-gel. In Step 504 an adhesion layer, e.g., titanium tetrachloride (TiCl₄), is applied, followed by the deposition of titanium oxide nanoparticles (NPs) in Step 506. For example, the NPs may be deposited by spin-coating or printing. The aluminum oxide precursor is applied in Step 508 as a solution, followed by a annealing. In Step 510 the perovskite is deposited, followed by the HTM. In Step 512 the metal electrode (e.g., gold) is formed, for example, by evaporation.

An extra thin layer Al₂O₃ coating is introduced to the conventional solution-based hybrid organic/inorganic perovskite sensitized solar cell fabrication processes, forming a TiO₂/Al₂O₃ bi-layered mesoporous scaffold structure for the perovskite coating. The addition of the extra thin layer Al₂O₃ enables this new structure solar cell to utilize the recently discovered unique property of the perovskite, which is an ambipolar charge transporter. Since the Al₂O₃ layer has a wider bandgap than the TiO₂, the photo excited electrons are transferred through the perovskite only when the Al₂O₃ is thick enough. If the Al₂O₃ is not too thick, some electrons may tunnel through the TiO₂ to transport those electrons to the anode together with perovskite-transported electrons. The application of the thin layer of the Al₂O₃ passivates the surface traps of the mesoporous TiO₂, thus eliminating recombination centers and suppressing degradation of the absorber material at the interface. By optimizing the Al₂O₃ thickness, a significant improvement in power conversion efficiency is obtained.

FIG. 6 is a flowchart illustrating a method for forming a passivated mesoscopic metal oxide. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. Generally however, the method follows the numeric order of the depicted steps. The method starts at Step 600.

Step 602 forms a mesoporous layer of a metal oxide. Step 604 coats the mesoporous layer of metal oxide with a passivating semiconductor layer having a bandgap wider than the metal oxide. More explicitly, forming the mesoporous layer of the metal oxide in Step 602 includes the following substeps. Step 602a deposits metal oxide nanoparticles, and Step 602b anneals. Coating the mesoporous layer of metal oxide with the passivating semiconductor layer in Step 604 includes the following substeps. Step 604a deposits a solution of passivating semiconductor precursors. Optionally, Step 604b hydrolyzes the passivating semiconductor precursors. For example, water may be removed using a low temperature process. Step 604c anneals the hydrolyzed precursor.

The metal oxide may be titanium oxide (TiO₂), tin oxide (SnO₂), zinc oxide (ZnO), niobium oxide (Nb₂O₅), tantalum oxide (Ta₂O₅), barium titanate (BaTiO₃), strontium titanate (SrTiO₃), zinc titanate (ZnTiO₃), or copper titanate (CuTiO₃). The passivating semiconductor may be aluminum oxide (Al₂O₃), silicon oxide (SiO₂), or zirconium oxide (ZrO₂).

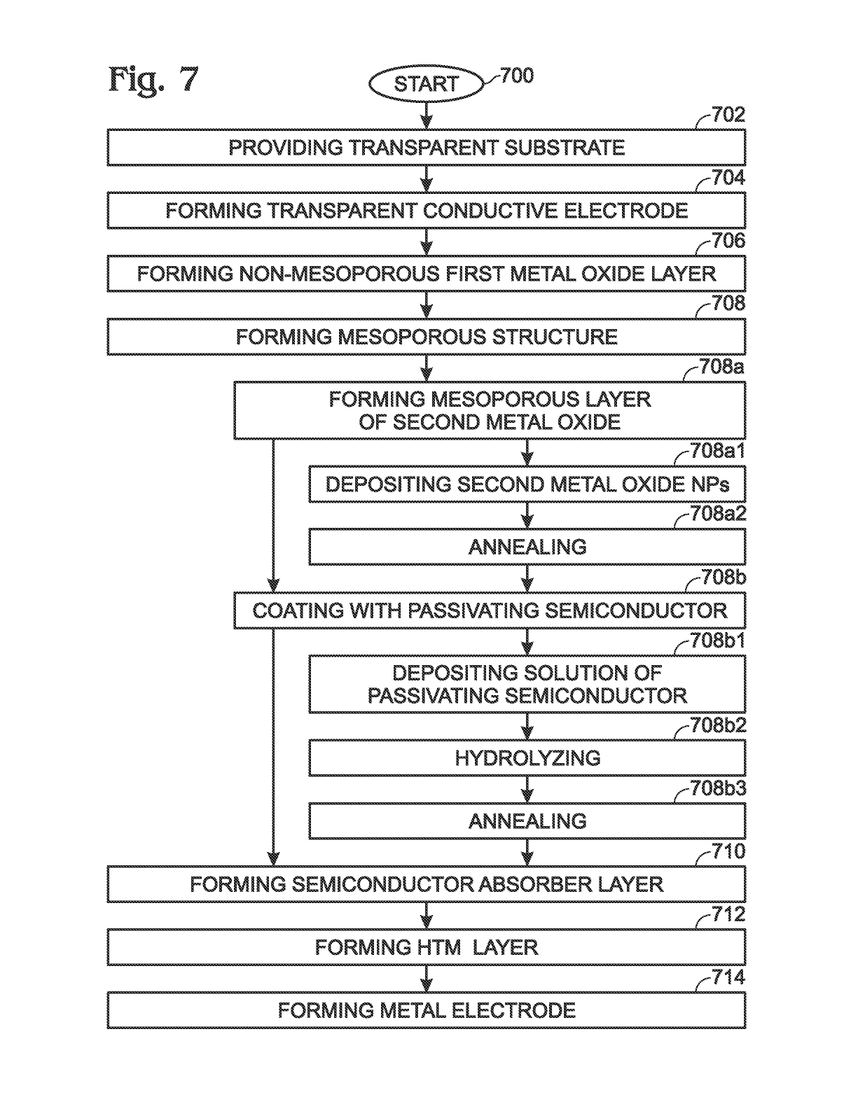

FIG. 7 is a flowchart illustrating a method for forming a surface-passivated mesoporous-structured solar cell. The method begins at Step 700. Step 702 provides a transparent substrate, which may for example be glass, quartz, or plastic. Step 704 forms a transparent conductive electrode overlying the transparent substrate, which may be FTO, ITO or IGZO, to name a few examples. Step 706 forms a non-mesoporous layer of a first metal oxide overlying the transparent conductive electrode. Step 708 forms a mesoporous structure overlying the non-mesoporous layer of first metal oxide as follows. Step 708a forms a mesoporous layer of a second metal oxide. Step 708b coats the mesoporous layer of second metal oxide with a passivating semiconductor layer having a bandgap wider than the second metal oxide. Step 710 forms a semiconductor absorber layer overlying the mesoporous structure comprising organic and inorganic components. Step 712 forms a HTM layer overlying the semiconductor absorber layer. Step 714 forms a metal electrode overlying the HTM layer.

In one aspect, forming the mesoporous layer of the second metal oxide in Step 708a comprises the following substeps. Step 708a1 deposits second metal oxide nanoparticles, and Step 708a2 anneals. Coating the mesoporous layer of second metal oxide with the passivating semiconductor layer in Step 708b comprises the following substeps. Step 708b 1 deposits a solution of passivating semiconductor precursors. Step 708b2 hydrolyzes the passivating semiconductor precursors, and Step 708b3 anneals. Again, hydrolysis may not be needed, as precursors may be decomposed to an appropriate oxide through exposure to the air.

In another aspect, the first and second metal oxides are independently selected from the following materials: TiO₂, SnO₂, ZnO, Nb₂O₅, Ta₂O₅, BaTiO₃, SrTiO₃, ZnTiO₃, and CuTiO₃. The passivating semiconductor is selected from the following materials: Al₂O₃, SiO₂, and ZrO₂. The HTM layer of Step 712 is typically an organic HTM material layer, such as spiro-OMeTAD.

The semiconductor absorber of Step 710 has the general formula of ABX_{Z}Y_{3-Z};

where “A” is an organic monocation;

where B is a transition metal dication;

where X and Y are inorganic monoanions; and,

where z is in a range of 0 to 1.5, as described in more detail above.

A surface-passivated mesoporous-structured solar call and associated fabrication processes have been provided. Examples of particular materials and process steps have been presented to illustrate the invention. However, the invention is not limited to merely these examples. Other variations and embodiments of the invention will occur to those skilled in the art.

We claim:

1. A surface-passivated mesoporous-structured solar cell comprising:
a transparent substrate;
a transparent conductive electrode overlying the transparent substrate;
a non-mesoporous layer of a first metal oxide overlying the transparent conductive electrode;
a mesoporous structure overlying the non-mesoporous layer of first metal oxide, the mesoporous structure comprising:
a mesoporous layer of a second metal oxide;
a passivating semiconductor layer coating the mesoporous layer of second metal oxide, having a bandgap wider than the second metal oxide;
a semiconductor absorber layer overlying the mesoporous structure comprising organic and inorganic components;
a hole-transport medium (HTM) layer overlying the semiconductor absorber layer; and,
a metal electrode overlying the HTM layer.

2. The solar cell of claim 1 wherein the passivating semiconductor layer has a bandgap greater than 3 electron volts (eV).

3. The solar cell of claim 1 wherein the first and second metal oxides are independently selected from a group consisting of titanium oxide (TiO₂), tin oxide (SnO₂), zinc oxide (ZnO), niobium oxide (Nb₂O₅), tantalum oxide (Ta₂O₅), barium titanate (BaTiO₃), strontium titanate (SrTiO₃), zinc titanate (ZnTiO₃), and copper titanate (CuTiO₃).

4. The solar cell of claim 1 wherein the passivating semiconductor layer is selected from a group consisting of aluminum oxide (Al₂O₃), silicon oxide (SiO₂), and zirconium oxide (ZrO₂).

5. The solar cell of claim 1 wherein the mesoporous structure comprises:
a mesoporous layer of TiO₂ nanoparticles; and,
a passivating semiconductor layer of Al₂O₃ coating the TiO₂ nanoparticles.

6. The solar cell of claim 5 wherein the Al₂O₃ coating has a thickness in a range of 1 to 10 nanometers (nm).

7. The solar cell of claim 5 wherein the Al₂O₃ coating has a thickness of a mono-layer.

8. The solar cell of claim 1 wherein the HTM layer is an organic HTM material.

9. The solar cell of claim 8 wherein the HTM layer is spiro-OMeTAD.

10. The solar cell of claim 1 wherein the semiconductor absorber layer has a general formula of ABX_{Z}Y_{3-Z};
where “A” is an organic monocation;
where B is a transition metal dication;
where X and Y are inorganic monoanions; and,
where z is in a range of 0 to 1.5.

11. The solar cell of claim 10 wherein the organic monocation “A” is selected from a group consisting of substituted ammonium cations with the general formula of R¹R²R³R⁴N;
where R is selected from a group consisting of hydrogen, and compounds derived from linear alkanes, branched alkanes, cycloalkanes, (poly)cycloalkanes, cis- and trans-linear alkenes, cis- and trans-branched alkenes, linear alkynes, branched alkynes, (poly)alkynes, aromatic hydrocarbons, (poly)aromatic hydrocarbons, heteroarenes, (poly)heteroarenes, thiophenes, (poly)thiophenes, (poly)anilines, and combination of above-mentioned elements;
wherein dication B is selected from could be selected from Pb²⁺, Sn²⁺, Cu²⁺, Ge²⁺, Zn²⁺, Ni²⁺, Fe²⁺, Mn²⁺, Eu²⁺, and Co²⁺; and,
wherein the monoanions X and Y are independently selected from a group consisting of halogenides of F—, Cl—, Br—, and I—, cyanides, and thiocyanides.

12. The solar cell of claim 10 wherein the semiconductor absorber layer is CH₃NH₃Pbl_{3-X}Cl_{X}.

13. A method for forming a surface-passivated mesoporous-structured solar cell, the method comprising:
providing a transparent substrate;
forming a transparent conductive electrode overlying the transparent substrate;
forming a non-mesoporous layer of a first metal oxide overlying the transparent conductive electrode;
forming a mesoporous structure overlying the non-mesoporous layer of first metal oxide as follows:
forming a mesoporous layer of a second metal oxide;
coating the mesoporous layer of second metal oxide with a passivating semiconductor layer having a bandgap wider than the second metal oxide;
forming a semiconductor absorber layer overlying the mesoporous structure comprising organic and inorganic components;
forming a hole-transport medium (HTM) layer overlying the semiconductor absorber layer; and,
forming a metal electrode overlying the HTM layer.

14. The method of claim 13 wherein forming the mesoporous layer of the second metal oxide comprises:
depositing second metal oxide nanoparticles;
annealing;
wherein coating the mesoporous layer of second metal oxide with the passivating semiconductor layer comprises:
depositing a solution of passivating semiconductor precursors;
hydrolyzing the passivating semiconductor precursors; and,
annealing.

15. The method of claim 13 wherein the first and second metal oxides are independently selected from a group consisting of titanium oxide (TiO₂), tin oxide (SnO₂), zinc oxide (ZnO), niobium oxide (Nb₂O₅), tantalum oxide (Ta₂O₅), barium titanate (BaTiO₃), strontium titanate (SrTiO₃), zinc titanate (ZnTiO₃), and copper titanate (CuTiO₃).

16. The method of claim 13 wherein coating the mesoporous layer of second metal oxide with the passivating semiconductor layer included using a passivating semiconductor selected from a group consisting of aluminum oxide (Al₂O₃), silicon oxide (SiO₂), and zirconium oxide (ZrO₂).

17. The method of claim 13 wherein forming the HTM layer includes forming an organic HTM material layer.

18. The method of claim 13 wherein forming the semiconductor absorber layer includes forming a semiconductor absorber having a general formula of ABX_{Z}Y_{3-Z};
where “A” is an organic monocation;
where B is a transition metal dication;
where X and Y are inorganic monoanions; and,
where z is in a range of 0 to 1.5.

19. A method for forming a passivated mesoscopic metal oxide, the method comprising:
forming a mesoporous layer of a metal oxide; and,
coating the mesoporous layer of metal oxide with a passivating semiconductor layer having a bandgap wider than the metal oxide.

20. The method of claim 19 wherein forming the mesoporous layer of the metal oxide comprises:
depositing metal oxide nanoparticles;
annealing;
wherein coating the mesoporous layer of metal oxide with the passivating semiconductor layer comprises:
depositing a solution of passivating semiconductor precursors;
hydrolyzing the passivating semiconductor precursors;
and,
annealing.

21. The method of claim 19 wherein forming the mesoporous layer includes using a metal oxide selected from a group consisting of titanium oxide (TiO₂), tin oxide (SnO₂), zinc oxide (ZnO), niobium oxide (Nb₂O₅), tantalum oxide (Ta₂O₅), barium titanate (BaTiO₃), strontium titanate (SrTiO₃), zinc titanate (ZnTiO₃), and copper titanate (CuTiO₃).

22. The method of claim 19 wherein coating the mesoporous layer of metal oxide with the passivating semiconductor layer included using a passivating semiconductor selected from a group consisting of aluminum oxide (Al₂O₃), silicon oxide (SiO₂), and zirconium oxide (ZrO₂).
